(19) United States
(12) Patent Application Publication
(10) Pub. No.: US 2019/0022568 A1
(43) Pub. Date: Jan. 24, 2019

(54) FLAME ARRESTOR FILTER FOR ELECTRIC EQUIPMENT

(71) Applicant: SIEMENS AKTIENGESELLSCHAFT, Munchen (DE)

(72) Inventor: Nicholas Chernansky, Pittsburgh, PA (US)

(21) Appl. No.: 16/070,442

(22) PCT Filed: Feb. 27, 2017
(86) PCT No.: PCT/US2017/019620

§ 371 Date: Jul. 16, 2018

Related U.S. Application Data
(60) Provisional application No. 62/301,062, filed on Feb. 29, 2016.

(51) Int. Cl. B01D 46/00; H05K 7/20; H05K 5/02; B01D 46/10

(52) U.S. Cl. CPC B01D 46/0093; H05K 7/20909; H05K 5/0213; B01D 2279/45; B01D 46/10; B01D 46/0005; B01D 2275/205; H05K 5/0217

(57) ABSTRACT

An enclosure (100) of an electric device includes an enclosure wall (105) and a flame arrestor filter (130) integrated into the enclosure wall (105), wherein the flame arrestor filter (130) is configured to filter a stream (160) of hot gases and particles occurring during an arc fault event inside the enclosure (100) such that the hot gases and particles are absorbed by the filter (130) and a filtered stream (170) of cooled gases exits the filter (130) to an outside of the enclosure (100).

### CROSS REFERENCE TO RELATED APPLICATIONS

This Application claims benefit of U.S. Provisional Patent Application No. 62/301,062 filed 29 Feb. 2016 in the United States Patent and Trademark Office, the content of which is herein incorporated by reference in its entirety.

### BACKGROUND

### 1. Field

Aspects of the present invention generally relate to electric equipment, such as for example variable frequency drives, power supplies, transformers and circuit breakers or the like, comprising one or more flame arrestor filter(s) for cooling gases discharged during an arc fault event.

### 2. Description of the Related Art

An electric device or equipment, such as for example variable frequency drive (VFD), power supply, transformer or circuit breaker, is typically housed in an enclosure or cabinet. Arc faults may occur within enclosures or cabinets due to for example faulty connections or user error. An internal short circuit may result in an arc fault. Air is ionized between two or more potentials in the electric device by the arc fault, causing an arc flash comprising a plasma cloud of rapidly expanding vaporized metallic materials. The plasma causes high pressures and temperatures to build up quickly, in fractions of a second, within the enclosure.

Arc fault conditions must either be contained within the enclosure or vented to the outside of the electric device enclosure. Arc fault effects are devastating for the equipment where it occurs and secondary effects such as explosive ejection of shrapnel and toxic gases cause serious hazards for personnel. While the electric arc is burning, significant damage of components inside the cabinet occurs in part due to the uncontrolled way the arc is burning. Additionally, the electric arc has a tendency to move inside the cabinet away from the source of energy. This way the damage inside is substantial and as a rule causes permanent damage to the entire cabinet and its contents.

Further, the electric device or equipment may comprise air inlets including air filter(s) for cooling purposes, but during an arc fault event, hot gases, plasma and debris may vent out of the air inlets, which can cause serious injury or death to personnel and property. Normal air filters break down or do not filter these gases under an arc event. Thus, there may exist a need for an improved electric equipment cabinet or enclosure, in particular improved arc fault resistant electric equipment.

### SUMMARY

Briefly described, aspects of the present invention relate to an electric device or electric equipment, including low and medium/high voltage equipment, in particular electric equipment comprising an enclosure, cabinet or housing, such as for example power supplies, transformers, circuit breakers, variable frequency drives, comprising one or more flame arrestor filter(s) for cooling gases discharged during an arc fault event.

According to a first aspect of the present invention, an enclosure of an electric device comprises an enclosure wall, and a flame arrestor filter integrated into the enclosure wall, wherein the flame arrestor filter is configured to filter a stream of hot gases and particles occurring during an arc fault event inside the enclosure such that the hot gases and particles are absorbed by the filter and a filtered stream of cooled gases exits the filter to an outside of the enclosure.

According to a second aspect of the present invention, a variable frequency drive (VFD) configured to be coupled to a utility power source and to provide output currents comprises a plurality of enclosures comprising a plurality of enclosure walls, and at least one flame arrestor filter integrated into at least one of the plurality of enclosure walls, wherein the flame arrestor filter is configured to filter a stream of hot gases and particles occurring during an arc fault event inside the enclosure such that the hot gases and particles are absorbed by the filter and a clean stream of cooled gases exits the filter to an outside of the enclosure.

### BRIEF DESCRIPTION OF THE DRAWINGS

FIG. 1 illustrates a first representation of a schematic cross-sectional view of a cabinet or enclosure of an electric device in accordance with an exemplary embodiment of the present invention.

FIG. 2 illustrates a second representation of a schematic cross-sectional view of a cabinet or enclosure of an electric device in accordance with an exemplary embodiment of the present invention.

FIG. 3 illustrates a representation of a perspective schematic view of a section of a cabinet or enclosure of a variable frequency drive in accordance with an exemplary embodiment of the present invention.

### DETAILED DESCRIPTION

To facilitate an understanding of embodiments, principles, and features of the present invention, they are explained hereinafter with reference to implementation in illustrative embodiments. In particular, they are described in the context of being an electric device and enclosure for an electric device, such as for example a power supply, transformer, circuit breaker, variable frequency drive (VFD) or the like, comprising one or more flame arrestor filter(s) for cooling gases discharged during an arc fault event. Embodiments of the present invention, however, are not limited to use in the described methods or system.

The components and materials described hereinafter as making up the various embodiments are intended to be illustrative and not restrictive. Many suitable components and materials that would perform the same or a similar function as the materials described herein are intended to be embraced within the scope of embodiments of the present invention.

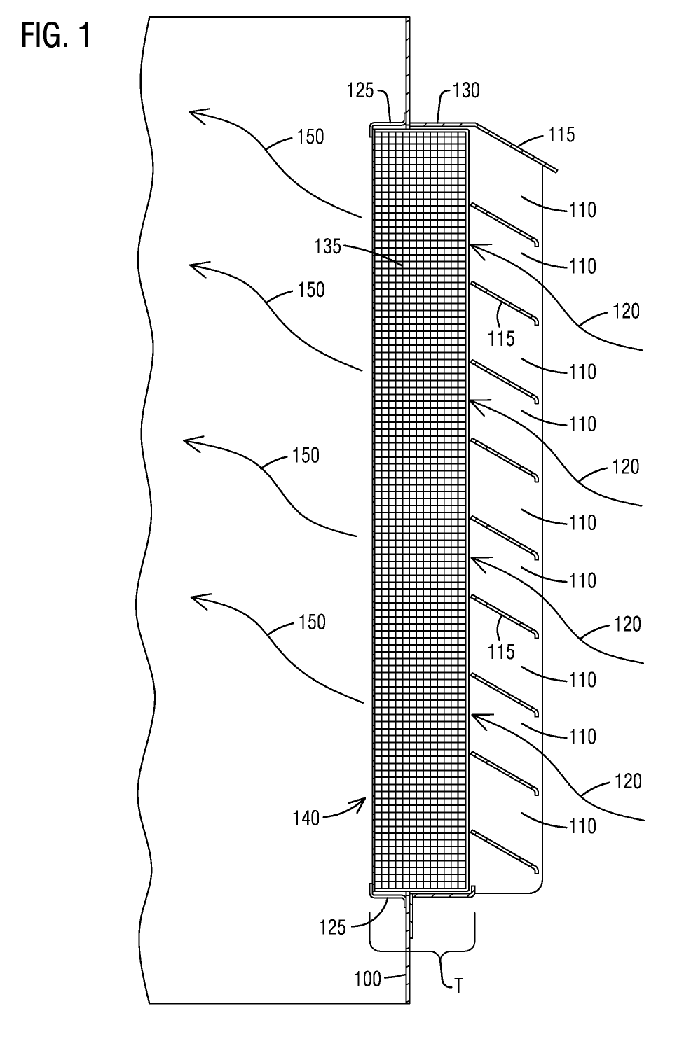

FIG. 1 illustrates a first representation of a schematic cross-sectional view of a cabinet or enclosure 100 of an electric device in accordance with an exemplary embodiment of the present invention.

The enclosure 100 houses one or more electric devices, such as for example power supplies, transformers, circuit breakers, variable frequency drives, etc. The enclosure 100 can be for example made of metal, and can be configured for example as steel enclosure. A cooling system of the electric device may include air intakes on a front, back, and/or sides of the enclosure 100. According to FIG. 1, the enclosure 100 comprises a plurality of air inlets 110 for cooling purposes of the electric equipment, wherein ambient air, illustrated by the arrows 120, is provided to the electric equipment positioned inside the enclosure 100 for cooling purposes. The air inlets 110 can comprise a plurality of stationary fins or louvers 115, for example for covering and protecting the air inlets 110.

Before the ambient air 120 enters the enclosure 100 and thus the electric device, the ambient air 120 is filtered. The enclosure 100 comprises one or more filter(s) 130. Under normal operating conditions of the electric device, the filter 130 acts as a standard air filter, wherein particles and dust are filtered from the ambient air stream 120 to protect the electric equipment inside the enclosure 100. The filtered air stream is represented by the arrows 150.

The filter 130 is an integral part of the enclosure 100, i.e., the filter 130 is integrated and forms a part, for example part of the front or side, of the enclosure 100. The enclosure 100 comprises one or more openings 140 for receiving the filter 130. The filter 130 is inserted into the opening 140 such that the filter 130 completely covers the opening 140 and is mounted securely and firmly in the opening 140. As FIG. 1 shows, the filter 130 is inserted about midway of its thickness T into the opening 140 of the enclosure 100. The enclosure 100, in particular at edges of the opening 140, can comprise support elements 125, designed for example as planes with folded edges or borders, on two opposite sides of the opening 140, which serve as a “stop” when arranging the filter 130 in the opening 140.

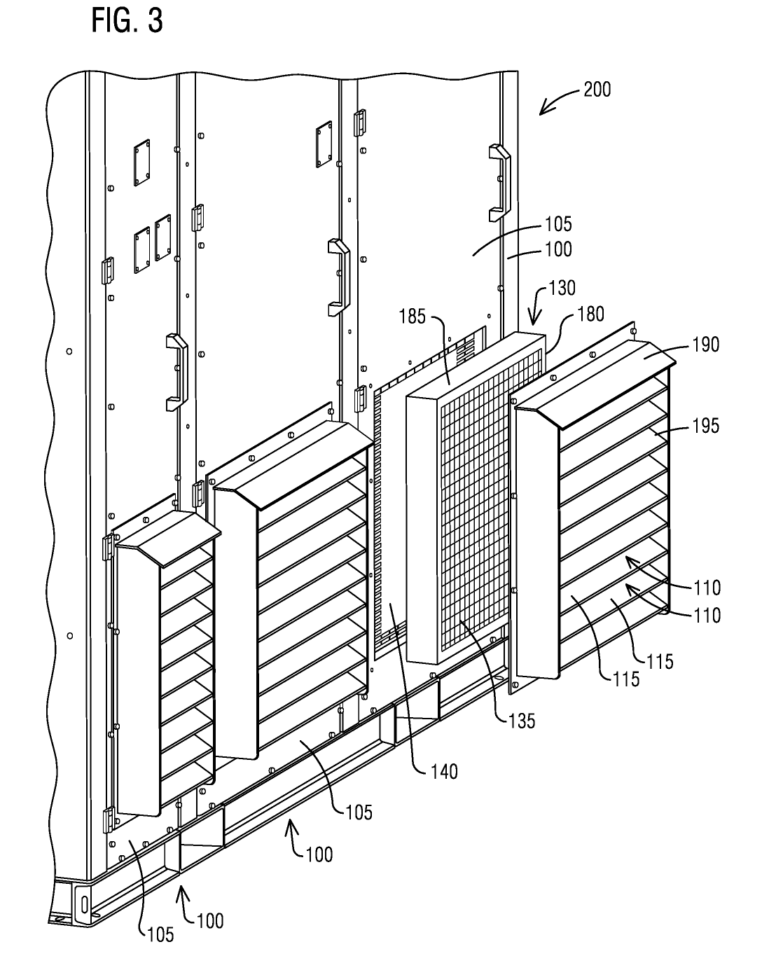

In an exemplary embodiment, the filter 130 comprises a rectangular design (see also FIG. 3), but can comprise many other shapes or forms as desired, wherein the enclosure 100 comprises the opening 140 with a corresponding shape or form for receiving the filter 130. The filter 130 can comprise an exemplary thickness T of about 3 (three) inches, but can comprise a thickness more or less than 3 inches.

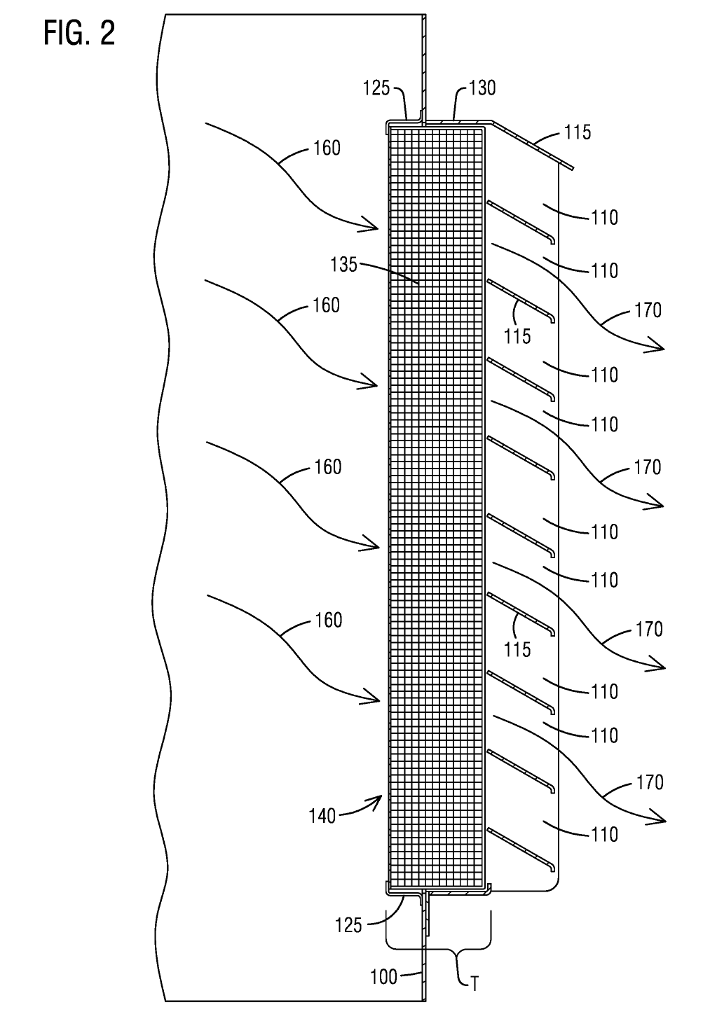

FIG. 2 illustrates a second representation of a schematic cross-sectional view of a cabinet or enclosure 100 of an electric device in accordance with an exemplary embodiment of the present invention. The schematic cross-sectional view of FIG. 2 corresponds to the view of FIG. 1, and same reference numerals used in FIG. 1 and FIG. 2 label the same components.

As described with reference to FIG. 1, under normal operating conditions of the electric device housed in the enclosure 100, i.e. not during an arc fault event, the ambient air stream 120 is provided to the electric equipment inside the enclosure 100 for cooling purposes, wherein the filter 130 acts as a standard air filter and filters particles and dust from the ambient air stream 120 to protect the electric equipment. But during an arc fault event in the enclosure 100, hot gases, plasma and debris may vent out of the air inlets 110, which can cause serious injury or death to personnel and property. Normal air filters break down or do not filter these gases under an arc event.

In order to improve the safety of an electric device during an arc fault event, the filter 130 is configured as flame arrestor filter adapted to filter and/or absorb hot gases, plasma and debris of an arc fault event. In an exemplary embodiment, the filter 130 can be configured as a metal filter filled with porous material 135, specifically a material with a high porosity, which has a high thermal conductivity and high specific heat (also known as specific heat capacity). The flame arrestor filter 130, when placed in an air stream, allows a continuous flow of air, but restricts the passage of particles including sparks, hot gases, plasma and debris of an arc fault event from the enclosure 100 to the outside. As FIG. 2 illustrates, in an arc fault event, hot gases and particles, represented by gas stream 160, enter the flame arrestor filter 130. The hot gases and particles stream 160 is filtered, wherein a cooled and filtered stream 170 exits the filter 130. The flame arrestor filter 130 absorbs the heat and particles during the arc fault event and also allows air to exit the enclosure 100 thereby lowering a pressure inside the equipment enclosure 100.

FIG. 3 illustrates a representation of a perspective schematic view of a section of a cabinet or enclosure 100 of a variable frequency drive (VFD) 200 in accordance with an exemplary embodiment of the present invention.

The VFD 200 can comprise multiple enclosures 100 adjacent to each other, wherein each enclosure 100 comprises multiple enclosure walls 105. At least one of the walls 105 of one or more enclosure(s) 100 comprises an opening 140 for receiving the flame arrestor filter 130. The flame arrestor filter(s) 130 are integrated into the enclosure walls 105. In our example, the enclosure walls 105 receiving the filters 130 are located at a front of the enclosures 100.

As described before, each flame arrestor filter 130 is configured to filter a stream 160 of hot gases and particles occurring during an arc fault event inside the enclosure 100 such that the hot gases and particles are absorbed by the filter 130 and a filtered stream 170 of cooled gases exits the filter 130 to an outside of the enclosure 100 (see FIG. 2). During the arc fault event, the flame arrestor filter 130 allows air to exit the enclosure 100 lowering a pressure inside the enclosure 100. At the same time, the flame arrestor filter 130 is configured to act as a regular air filter that filters an ambient air stream 120 before entering the enclosure 100 under normal conditions, i.e. not in an arc fault event (see FIG. 1).

According to an exemplary embodiment, the flame arrestor filter 130 can be configured as a filter panel 180 comprising a frame 185 for easy installation of the filter 130 within the opening 140. It should be noted that the flame arrestor filter 130 may not be configured as panel 180 with frame 185. The design of the flame arrestor filter 130 as filter panel 180 with frame 185 is optional and not critical to the function of the flame arrestor filter 130.

Further, FIG. 3 illustrates the air inlets 110 and stationary fins or louvers 115. In an example, the air inlets 110 and stationary fins 115 can be formed or assembled as a cooling air panel 190. The air panel 190 comprises a frame 195 wherein dimensions, such as length and width, of the frame 195 are slightly greater than those of the frame 185 so that the air panel 190 can be mounted over the filter panel 180. Specifically, the filter panel 180 is partly inserted in the air panel 190, and the air panel 190 with frame 195 are adapted to receive and hold the filter panel 180. When assembled, the filter panel 180 is not visible because the filter panel 180 is covered by the air panel 190. As described earlier with reference to FIG. 1, the filter 130 is inserted about midway of its thickness T into the opening 140 of the enclosure 100. The remaining section of the thickness of the panel 180 (filter 130) protruding the enclosure wall 105 toward the outside is covered by the air panel 190. The air panel 190 with the air inlets 110 and louvers 115 is securely mounted to the enclosure wall 105, for example by bolts or screws. It should be noted that the air panel 190 with frame 195 and air inlets 110 and stationary louvers 115 are optional and are not critical to the function of the flame arrestor filter 130. In other words, the VFD 200 may comprise the flame arrestor filter 130, but not the air panel 190 and/or air inlets 110 and louvers 115.

The provided solution for an arc fault resistant enclosure uses a manner, the flame arrestor filter, to cool hot gases and particles generated from an arc fault event. Such a configuration of an enclosure is a passive design, which requires no active component to properly function to provide the required characteristics, such as for example personnel protection, during the arc fault event. Since a VFD typically comprises air inlets and stationary fins for cooling purposes, the VFD can easily be equipped with the flame arrestor filter using an already existing opening for the air inlets without modifying the enclosure (retrofit solution).

While embodiments of the present invention have been disclosed in exemplary forms, it will be apparent to those skilled in the art that many modifications, additions, and deletions can be made therein without departing from the spirit and scope of the invention and its equivalents, as set forth in the following claims.

1.-12. (canceled)

13. A variable frequency drive (VFD) configured to be coupled to a utility power source and to provide output currents, the VFD comprising:
a plurality of enclosures comprising a plurality of enclosure walls, and
at least one flame arrestor filter integrated into at least one of the plurality of enclosure walls, wherein the flame arrestor filter is configured to filter a stream of hot gases and particles occurring during an arc fault event inside the enclosure such that the hot gases and particles are absorbed by the filter and a clean stream of cooled gases exits the filter to an outside of the enclosure.

14. The VFD of claim 13, wherein the at least one flame arrestor filter is further configured to filter an ambient air stream entering the enclosure for cooling purposes of the VFD positioned inside the enclosure.

15. The VFD of claim 13, wherein, during the arc fault event, the at least one flame arrestor filter allows air to exit the enclosure thereby lowering a pressure inside the enclosure.

16. The VFD of claims 13, wherein the flame arrestor filter is adapted as a filter panel comprising porous material.

17. The VFD of claim 16, wherein the at least one enclosure wall comprises an opening with support elements for receiving the filter panel, wherein the support elements limit insertion of the filter panel into the enclosure.

18. The VFD of claim 16, further comprising a cooling air panel including air inlets, stationary louvers and a frame, wherein the cooling air panel is mounted over the filter panel to cover the filter panel from an outside of the enclosure.

19. The VFD of claim 13, wherein the plurality of enclosures houses a power supply, a transformer and a circuit breaker.

20. The VFD of claim 16, wherein the porous material comprises a specific heat capacity that restricts passage of particles including sparks, plasma and debris of a gas stream in an arc fault event and cools the gas stream.
